(19) United States
(12) Patent Application Publication
(10) Pub. No.: US 2026/0090203 A1
(43) Pub. Date: Mar. 26, 2026

(54) Display Panel and Display Device Including the Same

(71) Applicant: LG Display Co., Ltd., Seoul (KR)

(72) Inventors: Jinhyeon Kim, Goyang-si (KR); Pureum Kim, Incheon (KR)

(21) Appl. No.: 19/290,173

(22) Filed: Aug. 4, 2025

(30) Foreign Application Priority Data
Sep. 24, 2024 (KR) 10-2024-0129130

(51) Int. Cl. H10K 59/121; H10K 59/00; H10K 59/12; H10K 71/12

(52) U.S. Cl. CPC H10K 59/121; H10K 59/1201; H10K 59/771; H10K 71/12

(57) ABSTRACT

Disclosed are a display panel and a display device including the same, in which a thickness of a light-emitting element layer in an outer area of the display panel is larger than a thickness of the light-emitting element layer in a central area thereof, so that viewing angle characteristic in the outer area of the display panel is improved.

### CROSS-REFERENCE TO RELATED APPLICATION

This application claims priority from Republic of Korea Patent Application No. 10-2024-0129130 filed on Sep. 24, 2024, which is hereby incorporated by reference in its entirety.

### BACKGROUND

### Field

The present disclosure relates to a display panel and a display device including the display panel.

### Description of Related Art

Display devices are implemented in a wide variety of forms, such as televisions, monitors, smartphones, tablet personal computers (PC), laptops, wearable devices, etc.

An organic light-emitting display (OLED) among the display devices displaying various information based on an image is a self-luminous device that emits light by itself, and has advantages in that a response speed is fast, light emission efficiency and luminance are high and a viewing angle is wide, and a contrast ratio and a color gamut are excellent.

Recently, as users'demands for high-quality images increase, development of a high-resolution display device is actively progressing.

### SUMMARY

Recently, a head-mounted display device (HMD) including an organic light-emitting display device have been developed. A user wears the head-mounted display device on his or her head such that a display screen of the device is positioned in front of his or her eyes. The head-mounted display device is used in various application fields such as virtual reality (VR), augmented reality (AR), mixed reality (MR), etc. and may play an important role in providing an immersive experience to a user.

In such a head-mounted display device, a user views the display panel through an optical system such as a lens, such that the viewing angle characteristic plays an important role, and in particular, light plays an important role in an outer area near the edge. In the head-mounted display device, a lens is positioned between the user's eyes and the display panel, and this lens may refract light such that the entire display panel is visible to the user. Therefore, the user should be able to clearly see not only the center but also the edge of the display panel.

In this case, when the viewing angle is narrow, a color change or brightness decrease may occur at the edge portion of the display panel, which may reduce the user's immersion and degrade the user experience. In addition, in the head-mounted display device, it is very important to maintain the quality of the screen even when the user turns or moves his or her head. This is why it is important to know how the view looks at various viewing angles when light is incident from the display panel to the lens. If the viewing angle characteristic of the head-mounted display device is not good, the luminance and color of the screen viewed by the user may be distorted.

The virtual reality display device may be formed using an organic light-emitting diode on silicon (OLEDoS) technology as a technology for forming an OLED on a silicon substrate. In general, the OLEDoS uses a silicon wafer instead of a glass or plastic substrate to manufacture a display device having a higher resolution and a higher density.

A microcavity structure is applied to the head-mounted display device having such a OLEDoS structure, thereby improving the efficiency of the display device and improving color gamut. The microcavity structure is a technology that increases color gamut by amplifying light of a specific wavelength in the organic light-emitting display device. The microcavity structure is composed of a thin dielectric layer and a reflective layer and is configured to amplify the emission efficiency of light in the OLED structure by resonating and strengthening light of a specific wavelength.

When the microcavity structure is applied to the head-mounted display device having the OLEDoS structure as described above, characteristics in different viewing angles may be different from each other. This means that a larger amount of reflection and interference may occur at a specific viewing angle when light is emitted from the display panel and travels to the lens.

In particular, light is not evenly transmitted to the outer area, such that lower luminance in which brightness is lowered may occur therein. In addition, in the outer area, a phenomenon in which the color looks different from the actual color at a specific viewing angle may occur, and thus a color distortion problem in which the color is distorted in accordance with the viewing angle may occur.

As described above, the problems such as the decrease in luminance or the color distortion occur in the outer area of the head-mounted display device, thereby deteriorating the user's experience. Thus, a technical solution for improving the viewing angle characteristics is required.

Accordingly, the inventors of the present disclosure have invented a display panel and a display device including the same capable of improving viewing angle characteristics in an outer area through various experiments.

A technical purpose to be achieved according to an embodiment of the present disclosure is to provide a display panel capable of improving viewing angle characteristics in an outer area and a display device including the same.

In addition, another technical purpose to be achieved according to an embodiment of the present disclosure is to provide a display panel and a display device including the same, capable of reducing occurrence of a luminance reduction problem and a color distortion problem of the display panel.

In addition, still another technical purpose to be achieved according to an embodiment of the present disclosure is to provide a display panel capable of maximizing an immersion feeling of a user using a head-mounted display device, and a display device including the same.

In addition, still yet another technical purpose to be achieved according to an embodiment of the present disclosure is to provide a mask frame assembly capable of allowing a light-emitting element layer having a larger thickness in an edge area to be deposited.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display panel according to an embodiment of the present disclosure includes: a substrate having a plurality of pixel areas corresponding to a plurality of pixels; a light-emitting element layer disposed on the substrate and corresponding to the plurality of pixels, wherein the light-emitting element layer has a greater thickness in an outer area than in a central area thereof.

In addition, the display panel according to an embodiment of the present disclosure may further include a plurality of reflective electrodes disposed between the substrate and the light-emitting element layer; a first electrode disposed between the light-emitting element layer and each reflective electrodes; and a second electrode disposed on the light-emitting element layer, wherein each pixel includes a plurality of sub-pixels, wherein distances between the reflective electrodes corresponding to sub-pixels of different colors and the second electrode are different.

In addition, a display device according to an embodiment of the present disclosure includes at least one display panel, wherein the display panel is embodied as the display panel according to the embodiment of the present disclosure as described above, and a casing accommodating therein the display panel.

In addition, a mask frame assembly according to an embodiment of the present disclosure includes a support frame; a first mask sheet disposed on the support frame and having a plurality of first openings defined therein, each first opening including a plurality of pattern holes defined by a plurality of boundary lines; a second mask sheet disposed on the first mask sheet and having a plurality of second openings defined therein; and a gap frame disposed between the first mask sheet and the second mask sheet and having a plurality of third openings defined therein, wherein sizes of the pattern holes in each first opening increase from the central area toward the outer area.

In addition, a method for manufacturing a display panel according to an embodiment of the present disclosure includes installing the mask frame assembly as described above, mounting a mother substrate including a plurality of cell areas on the mask frame assembly; and depositing a light-emitting element layer on each of the cell areas through the mask frame assembly using a deposition source disposed under the mask frame assembly.

According to the above-described embodiment of the present disclosure, the thickness in the outer area of the light-emitting element layer of the display panel is larger than the thickness in the central area thereof, thereby improving the viewing angle characteristic in the outer area of the display panel.

In addition, according to an embodiment of the present disclosure, the light-emitting element layer may be deposited such that the thickness in the outer area of the light-emitting element layer of the display panel is larger than the thickness in the central area of the light-emitting element layer, using the mask frame assembly including the first mask sheet functioning as a shadow forming mask sheet in which the sizes of the pattern holes of the first opening are set such that a size of the pattern hole increases as a position of the pattern hole changes from the central area toward the outer area, and the second mask sheet functioning as an open mask sheet.

In addition, according to an embodiment of the present disclosure, the microcavity effect in the outer area of the display panel to which the microcavity structure is applied may be adjusted to optimize the viewing angle characteristic, thereby reducing the occurrence of the luminance reduction problem and the color distortion problem of the display panel.

In addition, according to an embodiment of the present disclosure described above, the head-mounted display apparatus may be implemented using the display panel having improved viewing angle characteristics, thereby providing a consistent visual experience to a user and maximizing a user's immersion.

Accordingly, according to an embodiment of the present disclosure, the display panel and the display device having the high luminance may be implemented, such that power consumption of the display panel and the display device may be reduced to implement a low power display panel and the low power consumption display device.

Effects of the present disclosure are not limited to the effects mentioned above, and other effects not mentioned will be clearly understood by those skilled in the art from the description as set forth below. In addition to the above effects, specific effects of the present disclosure are described together while describing specific details for carrying out the present disclosure.

### BRIEF DESCRIPTION OF DRAWINGS

FIG. 1 is a schematic plan view of a display device according to an embodiment of the present disclosure.

FIG. 2 is a cross-sectional view of an area I-I′ of FIG. 1 according to an embodiment of the present disclosure.

FIG. 3 is an enlarged cross-sectional view of a stacked structure of a light-emitting element layer in an area I-I′ of FIG. 1 according to an embodiment of the present disclosure.

FIG. 4 is an enlarged cross-sectional view of an area II-II′ of FIG. 2 according to an embodiment of the present disclosure.

FIG. 5 is an enlarged cross-sectional view of an area III-III′ of FIG. 2 according to an embodiment of the present disclosure.

FIG. 6 is a graph illustrating a thickness change in each of areas of the light-emitting element layer in the area I-I′ of FIG. 1 according to an embodiment of the present disclosure.

FIG. 7 is a cross-sectional view of a mask frame assembly according to an embodiment of the present disclosure.

FIGS. 8 to 11 are plan views of a first mask sheet, a second mask sheet, a gap frame, and a mother substrate according to an embodiment of the present disclosure.

FIG. 12 is an enlarged view of one first opening corresponding to an area IV-IV′ of FIG. 8 according to an embodiment of the present disclosure.

FIG. 13 is a plan view showing a change in a thickness in a gradation form in a state in which a plurality of light-emitting element layers are stacked on a mother substrate according to an embodiment of the present disclosure.

FIG. 14 is a schematic perspective view of a head-mounted display device including a display device according to an embodiment of the present disclosure.

FIGS. 15 and 16 are top and side views showing a head-mounted display device implementing virtual reality, respectively according to an embodiment of the present disclosure.

FIG. 17 is a top view illustrating a head-mounted display device implementing virtual reality.

FIG. 18 illustrates an incident angle at which light from an edge area of a light-emitting element layer is incident to a lens according to an embodiment of the present disclosure.

FIGS. 19 to 21 show spectra at a viewing angle according to embodiment and Comparative Example.

FIGS. 22A, 22B, and 22C illustrate a luminance deviation based on a position according to embodiment and Comparative Example.

FIGS. 23A, 23B, and 23C illustrate a color deviation based on a position according to embodiment and Comparative Example.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims. A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify an entirety of the list of elements and may not modify the individual elements of the list. In interpretation of numerical values, an error or tolerance therein may occur even when there is no explicit description thereof. In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween. Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved. It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations. The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions. In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified. As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

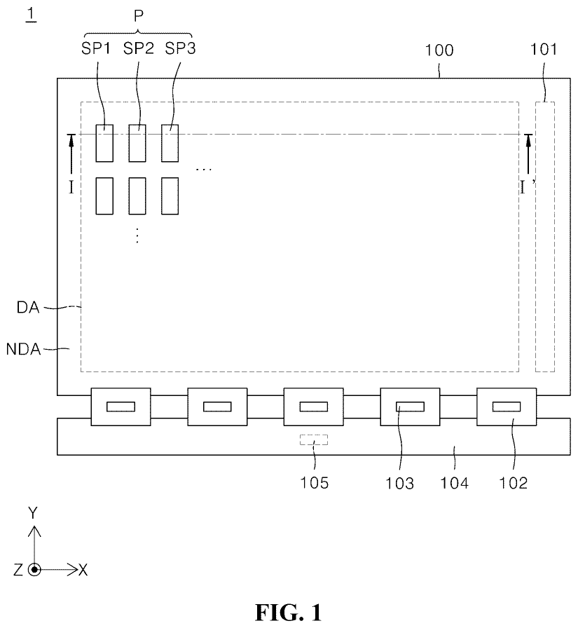

Hereinafter, a display panel and a display device according to an embodiment of the present disclosure will be described in detail with reference to FIG. 1. An example in which the display device 1 described below is embodied as an organic electroluminescence display device (organic light-emitting diode display device) is described below. However, embodiments of the present disclosure are not limited thereto.

The display device 1 may include a substrate 100 including a display area DA and a non-display area NDA surrounding a periphery of the display area DA. The display device 1 may include the substrate 100, a source driver integrated circuit (IC) 103, a flexible film 102, a circuit board 104, and a timing controller 105.

The substrate 100 may be made of glass or plastic such as polyimide. However, embodiments of the present disclosure are not limited thereto, and the substrate 100 may be made of a semiconductor material such as a silicon wafer.

The display area DA on the substrate 100 may include a plurality of sub-pixels SP1, SP2, and SP3 respectively formed in intersection areas in which a plurality of data lines extending in a first direction and a plurality of gate lines extending in a second direction intersecting the first direction intersect each other. The first direction described herein may be an X-axis direction, the second direction described herein may be a Y-axis direction, and a Z-axis direction described herein may be a direction perpendicular to the X-axis and the Y-axis. In addition, in the present disclosure, an example in which one pixel P is composed of the first sub-pixel SP1, the second sub-pixel SP2, and the third sub-pixel SP3 will be described. However, embodiments of the present disclosure are not limited thereto, and additional sub-pixels may be further included in one pixel P.

The sub-pixels SP1, SP2, and SP3 may be implemented to emit light of the same color, such as white light, or may be implemented to emit light of different colors, such as red, green, and blue light, respectively. Hereinafter, an embodiment in which the first sub-pixel SP1 emits red light, the second sub-pixel SP2 emits green light, and the third sub-pixel SP3 emits blue light will be described. The plurality of sub-pixels SP1, SP2, and SP3 may be arranged in a matrix form arranged in a plurality of rows and columns.

A gate driver 101 positioned at one side or each of both opposing sides of the display area DA may be disposed in the non-display area NDA and on the substrate 100. The gate driver 101 may be implemented in a gate-in-panel (GIP) manner. The gate driver 101 may supply gate signals to the gate lines GL according to a gate control signal GCS input from the timing controller 105.

The source driver integrated circuit 103 may receive digital video data and a source control signal from the timing controller 105. The source driver integrated circuit 103 may convert the digital video data into analog data voltages according to a source control signal and supply the analog data voltages to the data lines DL. The source driver integrated circuit 103 may be manufactured as a driving chip in a chip on film (COF) or chip on plastic (COP) manner and may be mounted on a plurality of flexible films 102. The circuit board 104 may be attached to the plurality of flexible films 102. A plurality of circuits implemented as driving chips such as the timing controller 105 may be mounted on the circuit board 104.

The timing controller 105 may receive the digital video data and a timing signal from an external system board via a cable of the circuit board 104. The timing controller 105 may supply the gate control signal for controlling the operation timing of the gate driver 101 and the source control signal for controlling the source driver integrated circuits 103 based on the timing signal.

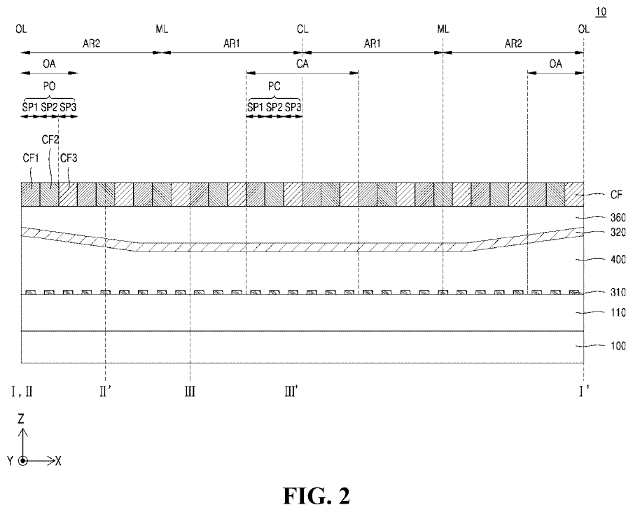

Hereinafter, a cross-section of the stacked structure of the display panel 10 will be described in more detail with further reference to FIGS. 2 to 5.

The substrate 100 may be made of glass or plastic such as polyimide. However, embodiments of the present disclosure are not limited thereto, and the substrate 100 may be made of a semiconductor material such as a silicon wafer. For example, the substrate 100 may be a single crystal silicon wafer formed by growing single crystal silicon (Si) or may be a wafer made of various semiconductor materials. Hereinafter, a OLEDoS (OLED on Si wafer) structure in which the light-emitting element layer 400 including an organic light-emitting element is disposed on the substrate 100 as a silicon wafer will be described as by way of example. However, embodiments of the present disclosure are not limited thereto.

A circuit area 110 may be disposed on the substrate 100. The circuit element layer 200 in which various circuit-related elements such as a plurality of thin-film transistors, a storage capacitor, and various signal lines such as gate lines or data lines are disposed may be disposed in the circuit area 110. For example, the plurality of thin-film transistors may include a switching thin-film transistor, a driving thin-film transistor, and a sensing thin-film transistor. A separate thin-film transistor may be disposed in an area corresponding to each of the sub-pixels SP1, SP2, and SP3.

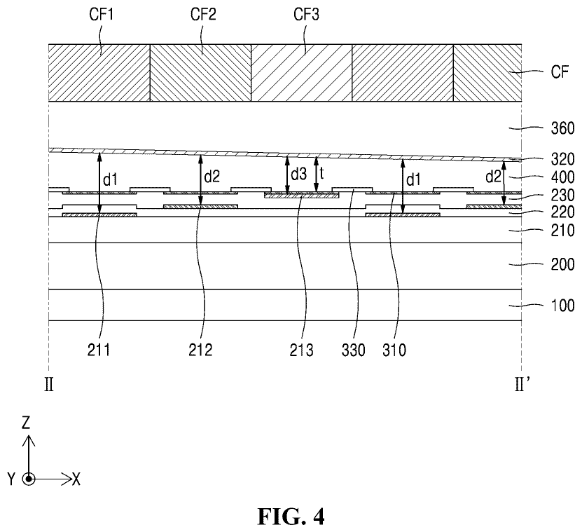

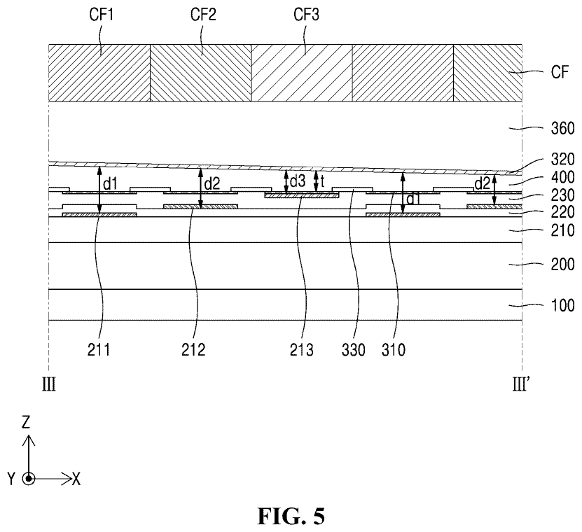

Referring to FIGS. 4 and 5, the circuit area 110 may include a first insulating layer 210, a first reflective electrode 211, a second insulating layer 220, a second reflective electrode 212, a third insulating layer 230, and a third reflective electrode 213 which are disposed on the circuit element layer 200.

FIG. 4 is a partially enlarged cross-sectional view of an area II-II′ in a second area AR2 of FIG. 2 according to one embodiment, and FIG. 5 is a partially enlarged cross-sectional view of an area III-III′ in a first area AR1 of FIG. 2 according to one embodiment. The II-II′ area and the III-III′ area respectively shown in FIGS. 4 and 5 may be identical with each other except that the II-II′ area and the III-III′ area respectively shown in FIGS. 4 and 5 are different from each other in terms of a thickness and a thickness change of the light-emitting element layer 400.

Each of the first insulating layer 210, the second insulating layer 220, and the third insulating layer 230 may be formed as a single layer or multiple layers made of an inorganic material such as silicon nitride, aluminum nitride, zirconium nitride, titanium nitride, hafnium nitride, tantalum nitride, silicon oxide, aluminum oxide, or titanium oxide. However, embodiments of the present disclosure are not limited thereto, and each of the first insulating layer 210, the second insulating layer 220, and the third insulating layer 230 may be formed as a single layer or multiple layers made of an organic material such as acryl resin, epoxy resin, phenolic resin, polyamide resin, polyimide resin, and the like.

Each of the first reflective electrode 211, the second reflective electrode 212, and the third reflective electrode 213 may include a metal material having high reflection efficiency, and for example, may be made of a metal material including silver (Ag) or silver (Ag). However, embodiments of the present disclosure are not limited thereto.

The first insulating layer 210 may be disposed on the circuit element layer 200 to cover the entire surface of the substrate 100. The first reflective electrode 211 may be disposed in the first sub-pixel SP1 and on the first insulating layer 210. That is, the first reflective electrode 211 may be disposed in each of the plurality of first sub-pixels SP1.

The second insulating layer 220 may be disposed on the first reflective electrode 211 to cover the entire surface of the substrate 100. The second reflective electrode 212 may be disposed in the second sub-pixel SP2 and on the second insulating layer 220. That is, the second reflective electrodes 212 may be disposed in each of the plurality of second sub-pixels SP2.

The third insulating layer 230 may be disposed on the second reflective electrode 212 to cover the entire surface of the substrate 100. The third reflective electrode 213 may be disposed in the third sub-pixel SP3 and on the third insulating layer 230. That is, the third reflective electrodes 213 may be disposed in each of the plurality of third sub-pixels SP3.

A first electrode 310 may be disposed on each of the first reflective electrode 211, the second reflective electrode 212, and the third reflective electrode 213. That is, the first electrode 310 may be disposed in each of the plurality of sub-pixels SP. The first electrode 310 may be electrically connected to the light-emitting element layer 400 to be described later, and may function as an anode electrode. For example, the first electrode 310 may include a transparent conductive material or a transflective metal material. However, embodiments of the present disclosure are not limited thereto.

The adjacent first electrodes 310 respectively disposed in adjacent sub-pixels SP may be disposed to be spaced apart from each other. A bank 330 may be disposed on the first electrode 310. The bank 330 is formed to cover an end of the first electrode 310, thereby preventing current from being concentrated to the end of the first electrode 310. The bank 330 may be formed as a single layer or a plurality of layers made of an inorganic material such as silicon nitride (SiNx) or silicon oxide (SiOx). However, embodiments of the present disclosure are not limited thereto. In addition, the bank 330 may be made of an organic material, and may include, for example, a material made of polyimide, acryl, or benzocyclobutene-based resin. In addition, the bank 330 may be implemented as a black bank including a black material. The bank 330 may be referred to as a fence.

The first electrode 310 disposed on the third reflective electrode 213 may directly contact the third reflective electrode 213. However, embodiments of the present disclosure are not limited thereto. For example, a fourth insulating layer formed on the third reflective electrode 213 so as to cover the entire surface of the substrate 100 may be additionally disposed between the third reflective electrode 213 and the first electrode 310, so that the third reflective electrode 213 and the first electrode 310 may be disposed to be spaced apart from each other by a predetermined distance without contacting each other.

The light-emitting element layer 400 may be disposed on the first electrode 310, and a second electrode 320 may be disposed on the light-emitting element layer 400. The second electrode 320 may be formed over the entire surface of the substrate 100 so as to be commonly connected to the light-emitting element layer 400 extending across all sub-pixels. Accordingly, the second electrode 320 may be referred to as a common electrode.

The second electrode 320 may be electrically connected to the light-emitting element layer 400 and may function as a cathode electrode. For example, the second electrode 320 may include a transparent conductive material such as indium tin oxide (ITO) or indium zinc oxide (IZO) or a transflective conductive material. However, embodiments of the present disclosure are not limited thereto.

An encapsulation layer 360 that blocks external moisture and oxygen may be formed on the second electrode 320. The encapsulation layer 360 may include an inorganic insulating material such as silicon oxide (SiOx) and silicon nitride (SiNx) or an organic insulating material such as acrylic resin and epoxy resin and may be formed as a single layer or multiple layers.

A color filter layer CF may be disposed on the encapsulation layer 360. For example, the color filter may include a red first color filter CF1 provided in the first sub-pixel SP1, a green second color filter CF2 provided in the second sub-pixel SP2, and a blue third color filter CF3 provided in the third sub-pixel SP3. The light-emitting element layer 400 according to an embodiment of the present disclosure may be implemented to emit white light.

Accordingly, in the first sub-pixel SP1, white light emitted from the light-emitting element layer 400 passes through the first color filter CF1 such that only red light is emitted out thereof. In the second sub-pixel SP2, white light emitted from the light-emitting element layer 400 passes through the second color filter CF2 such that only green light is emitted out thereof. In the third sub-pixel SP3, white light emitted from the light-emitting element layer 400 passes through the third color filter CF3 such that only blue light is emitted out thereof.

The first reflective electrode 211, the second reflective electrode 212, and the third reflective electrode 213 may reflect light emitted from the light-emitting element layer 400 therefrom upwardly toward the second electrode 320. That is, the light emitted from the light-emitting element layer 400 may be reflected between the second electrode 320, the first reflective electrode 211, the second reflective electrode 212, and the third reflective electrode 213 to constructively interfere with each other, and then may pass through the second electrode 320 and be emitted to the outside.

Since the first reflective electrode 211, the second reflective electrode 212, and the third reflective electrode 213 are disposed in different layers, respective spacings between the first reflective electrode 211, the second reflective electrode 212, and the third reflective electrode 213 and the first electrode 310 may be set to be different from each other in sub-pixels emitting light of different colors.

For example, a first distance d1 which is a distance between the first reflective electrode 211 and the second electrode 320, may be greater than a second distance d2, which is a distance between the second reflective electrode 212 and the second electrode 320. A second distance d2, which is a distance between the second reflective electrode 212 and the second electrode 320, may be greater than a third distance d3, which is a distance between the third reflective electrode 213 and the second electrode 320. As described above, the first distance d1, the second distance d2, and the third distance d3 are different from each other, so that light of different colors may be extracted using the microcavity effect.

Specifically, as the distance between the first reflective electrode 211 and the second electrode 320 is larger, the light extraction efficiency of the long wavelength may be improved, so that the light extraction efficiency of the red light in the first reflective electrode 211 and the second electrode 320 may be improved. As the distance between third reflective electrode 213 and the second electrode 320 is smaller, the light extraction efficiency of the short wavelength may be improved, so that the light extraction efficiency of the blue light between the third reflective electrode 213 and the second electrode 320 may be improved. In addition, since the distance between the second reflective electrode 212 and the second electrode 320 is smaller than the distance between the first reflective electrode 211 and the second electrode 320 and is larger than the distance between the third reflective electrode 213 and the second electrode 320, light extraction efficiency of green light may be improved.

Accordingly, according to the present disclosure, the microcavity structure may be applied to the display panel 10 to emit light, such that the light extraction efficiency of red light is improved in the first sub-pixel SP1 to emit red light, the light extraction efficiency of green light is improved in the second sub-pixel SP2 to emit green light, and the light extraction efficiency of blue light is improved in the third sub-pixel SP3 to emit blue light.

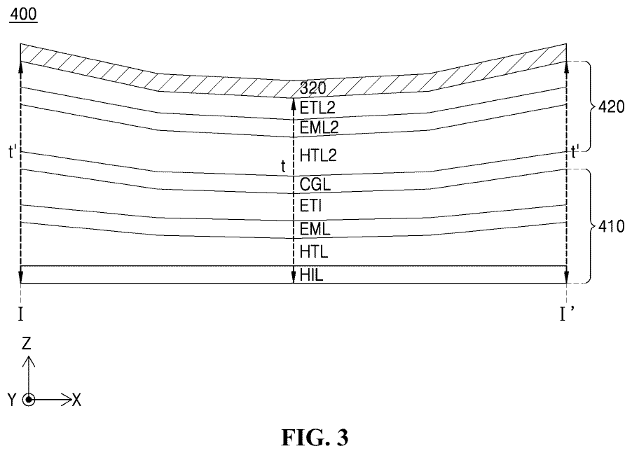

Hereinafter, a stacked structure of the light-emitting element layer 400 will be described with reference to FIG. 3. The light-emitting element layer 400 may be formed on the first electrode 310 so as to extend across the plurality of pixels P. Although the present disclosure is described based on an embodiment in which the light-emitting element layer 400 has a tandem structure in which two stacks are stacked, embodiments of the present disclosure are not limited thereto, and the light-emitting element layer 400 may have a tandem structure in which three or more stacks are stacked. For example, the light-emitting element layer 400 may include a first stack 410, a charge generation layer CGL, and a second stack 420 sequentially stacked upwardly. The first stack 410 may include a hole injection layer HIL, a hole transport layer HTL, a first organic light-emitting layer EML, and an electron transport layer ETL, which are sequentially stacked upwardly, and the second stack 420 may include a second hole transport layer HTL2, a second light-emitting layer EML2, and a second electron transport layer ETL2, which are sequentially stacked upwardly.

The hole injection layer HIL may serve to efficiently inject holes from the first electrode 310 into the organic light-emitting layer EML. The hole transport layer HTL may serve to help holes move to the organic light-emitting layer EML. The organic light-emitting layer EML is a layer that substantially emits light, and holes and electrons may be recombined with each other therein to emit light. The electron transport layer ETL may serve to inject electrons and move the electrons to the organic light-emitting layer EML. The charge generation layer CGL may supply charges to the first stack 410 and the second stack 420 to adjust charge balance between the first stack 410 and the second stack 420. The charge generation layer CGL may be formed as a single layer. However, embodiments of the present disclosure are not limited thereto, and the charge generation layer CGL may be formed as a plurality of layers including an N-type charge generation layer and a P-type charge generation layer.

The first stack 410 and the second stack 420 emit light of different colors such that the light-emitting element layer 400 including the first stack 410 and the second stack 420 may emit white light.

In one example, the light-emitting element layer 400 is formed to cover the entire surface of the substrate 100, but may not have the form thickness in all areas of the substrate 100 and may have different thicknesses in the different areas thereof.

Referring to FIG. 2, a line passing through a center in the left-right direction of the light-emitting element layer 400 in the side cross-sectional view of the display panel 10 may be defined as a center line CL, and a predetermined area around the center line CL may be defined as a center area CA. In the present disclosure, in the central area CA, the pixel P positioned closest to the center line CL may be defined as a central pixel PC, and the area including the central pixel PC may be defined as the central area CA. For example, when the center line CL passes through a boundary of the pixels P adjacent to each other, both the two closest pixels P to the center line CL may become the center pixels PC, and the area including the two center pixels PC may be defined as the center area CA.

In one example, in the side cross-sectional view of the display panel 10, a line passing through each of both left and right ends of the light-emitting element layer 400 may be defined as the outermost line OL, and a predetermined area adjacent to the outermost line OL may be defined as the outermost area OA. In the present disclosure, in the outermost area OA, the pixel P positioned closest to the outermost line OL may be defined as the outermost pixel PO, and an area including the outermost pixel PO may be defined as the outermost area OA. In addition, the outermost area OA referred to herein may be defined as an edge area.

A line positioned at a middle of an area between the center line CL and the outermost line OL may be defined as a middle line ML. In this case, an area between the center line CL and the middle line ML may be defined as a first area AR1, and an area between the middle line ML and the outermost line OL may be defined as a second area AR2. Accordingly, a pair of first areas AR1 may be respectively positioned on both opposing sides of the center line CL, and the first area AR1 and the second area AR2 may be disposed between the center line CL and each outermost line OL. The central area CA may be included in the first area AR1, and the outermost area OA may be included in the second area AR2. In addition, an outer area defined in the present disclosure may mean a predetermined area included in the second area AR2 including the outermost area OA. However, embodiments of the present disclosure are not limited thereto. For example, an area further away from the center line CL, that is, closer to the outermost line OL as compared to the center area CA may be defined as the outer area. In this case, the outer area may be defined as a relative concept that the outer area is outside the central area CA.

The central line CL, the outermost line OL, the middle line ML, the central area CA, the outermost area OA, the first area AR1, and the second area AR2 are conceptual distinctions introduced to describe the present disclosure. The light-emitting element layer 400 is not physically distinguishable using the conceptual distinctions.

A thickness t in the outer area of the light-emitting element layer 400 as described above may be larger than a thickness t in the central area CA of the light-emitting element layer 400. That is, the thickness of the outermost pixel PO in the outermost area OA of the light-emitting element layer 400 may be larger than the thickness of the central pixel PC in the central area CA of the light-emitting element layer 400.

For example, the thickness of the light-emitting element layer 400 may increase as the light-emitting element layer 400 extends from the central area CA toward the outer area. In this case, the thickness of the light-emitting element layer 400 may gradually increase in a gradation manner. For example, the thickness of the light-emitting element layer 400 may continuously increase in an entirety of an area from the central area CA toward the outer area. However, embodiments of the present disclosure are not limited thereto, and the thickness may be maintained constant without increasing in each of some areas. Therefore, the meaning that the thickness of the light-emitting element layer 400 increases as the light-emitting element layer 400 extends from the central area CA toward the outer area is not limited to change of the thickness so that the thickness increases in each of all areas and may include a case in which the thickness is constant in each of some areas. That is, the light-emitting element layer 400 according to the present disclosure does not have any area in which the thickness thereof decreases as the area extends in a direction from the central area CA toward the outer area but may have an area in which the thickness thereof increases or is constantly maintained as the area extends in a direction from the central area CA toward the outer area.

A thickness t′ in the outermost area of the light-emitting element layer 400 described above may be greater than the thickness t of a portion of the light-emitting element layer 400 disposed in another area. The rates of change of the thickness t of the light-emitting element layer 400 in the different areas may be set to be different from each other. Specifically, the rate of change in the thickness in the area may be more significant as the area is closer to the outer area of the light-emitting element layer 400.

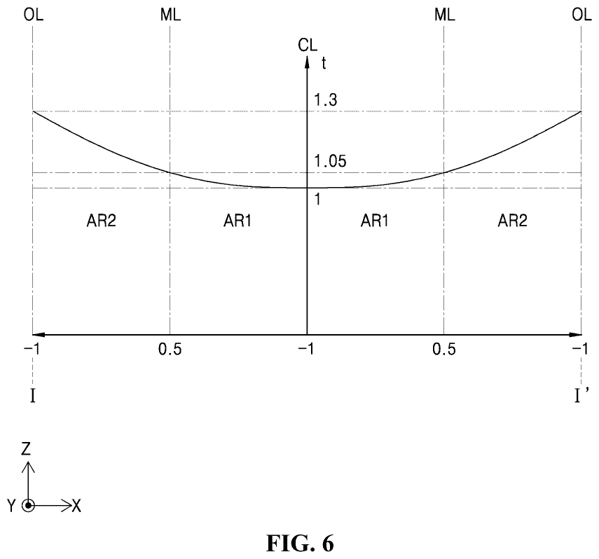

Referring further to FIG. 6, the thickness change rate in the second area AR2 may be set to be greater than the thickness change rate in the first area AR1 of the light-emitting element layer 400. For example, when the thickness of the light-emitting element layer 400 at the center line CL is defined as 1, the thickness of the light-emitting element layer 400 at the middle line ML which is the outer end of the first area AR1 may increase to a numerical range of about 0% to 5% of the thickness of the light-emitting element layer 400 at the center line CL. In addition, the thickness of the light-emitting element layer 400 at the outermost line OL which is the outer end of the second area AR2 may be set to increase to a numerical range of approximately 10% to 30% of the thickness of the light-emitting element layer 400 at the center line CL.

As described above, the thickness change rate in the second area AR2 may be set to be greater than the thickness change rate in the first area AR1 of the light-emitting element layer 400, such that the viewing angle characteristic in the outer area of the light-emitting element layer may be more effectively improved. In addition, the minimum thickness change rate at the outermost line OL is set to be larger by at least two times than the maximum thickness change rate at the middle line ML, so that the viewing angle characteristic improvement in the edge area of the light-emitting element layer 400 may be more effectively achieved. In addition, the thickness of the light-emitting element layer 400 at the outermost line OL is set not to exceed 30% of the thickness of the light-emitting element layer 400 at the central line CL, so that a difference between the viewing angle characteristics of the outer area and the other areas is not excessive.

Referring to FIG. 3, the thickness of each of the hole transport layer HTL, the second hole transport layer HTL2, the electron transport layer ETL, and the second electron transport layer ETL2 among the layers included in the light-emitting element layer 400 may increase as each layer extends from the central area CA of the light-emitting element layer 400 toward the outer area thereof. In addition, the thickness of each of the hole injection layer HIL, the organic light-emitting layer EML, the charge generation layer CGL, and the second organic light-emitting layer EML2 may be maintained constant in the entire area of the light-emitting element layer 400. Each of the hole transport layer HTL, the second hole transport layer HTL2, the electron transport layer ETL, and the second electron transport layer ETL2 acts as an optical compensation layer that moves holes or electrons. Thus, even though each of the hole transport layer HTL, the second hole transport layer HTL2, the electron transport layer ETL, and the second electron transport layer ETL2 has the change in thickness, this change does not affect the light emission of the light-emitting element layer 400. On the other hand, each of the hole injection layer HIL, the organic light-emitting layer EML, the charge generation layer CGL, and the second organic light-emitting layer EML2 may substantially affect the light-emitting effect of the light-emitting element layer 400. Thus, it is preferable that the thickness of each of the hole injection layer HIL, the organic light-emitting layer EML, the charge generation layer CGL, and the second organic light-emitting layer EML2 is maintained as constant as possible. When the electron injection layer EIL is additionally included in the light-emitting element layer 400, it is preferable that the thickness of the electron injection layer EIL is maintained at a constant value.

As described above, the respective distances between the respective reflective electrodes corresponding to the respective sub-pixels SP included in one pixel P and emitting light of different colors and the second electrode 320 may be different from each other.

In one example, the distances between the reflective electrodes of the sub-pixels emitting light of the same color and the second electrode 320 may be set such that the distance between the reflective electrode in the sub-pixel closer to the outer area and the second electrode is greater than the distance between the reflective electrode in the sub-pixel closer to the central area CA and the second electrode. For example, a first distance d1, which is a distance between the first reflective electrode 211 in the first sub-pixel SP1 located in the second area AR2 and the second electrode 320, may be greater than a first distance d1, which is a distance between the first reflective electrode 211 in the first sub-pixel SP1 located in the first area AR1 and the second electrode 320. In addition, even in the first sub-pixels SP1 in the same first area AR1 or second area AR2, the first distance d1 between the first reflective electrode 211 in the sub-pixel closer to the outer area and the second electrode is greater than the first distance d1 between the first reflective electrode 211 in the sub-pixel closer to the central area CA and the second electrode. This configuration of the first distance d1 may be equally applied to each of the second distance d2, which is the distance between the second reflective electrode 212 and the second electrode 320, and the third distance d3, which is the distance between the third reflective electrode 213 and the second electrode 320.

A thickness of the second electrode 320 disposed on the light-emitting element layer 400 may increase as the second electrode extends from the central area CA toward the outer area depending on the change in the thickness of the light-emitting element layer 400. The thickness of the light-emitting element layer 400 may be changed in a symmetrical manner around the center line CL. The thickness of the second electrode 320 may be changed in a symmetrical manner around the center line CL.

Since the encapsulation layer 360 disposed on the light-emitting element layer 400 and the second electrode 320 may function as a planarization layer, the thickness of the encapsulation layer 360 may decrease as the encapsulation layer 360 extends from the central area CA toward the outer area. That is, the thickness change rate of the encapsulation layer 360 is opposite to the thickness change rate of the light-emitting element layer 400. Thus, the upper surface of the encapsulation layer 360 may be kept in a planarized state. Since the color filter layer CF is disposed on the encapsulation layer 360 having the planarized upper surface, the color filter layer CF may be stably disposed on the planarized upper surface of the encapsulation layer 360 without being affected by the change in the thickness of the light-emitting element layer 400.

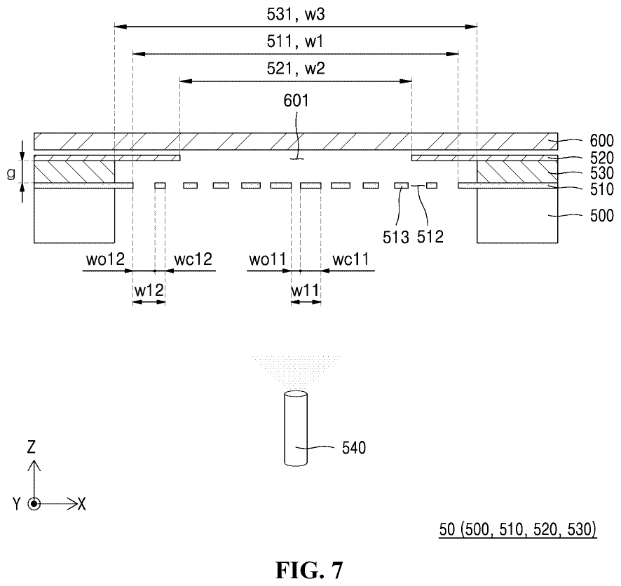

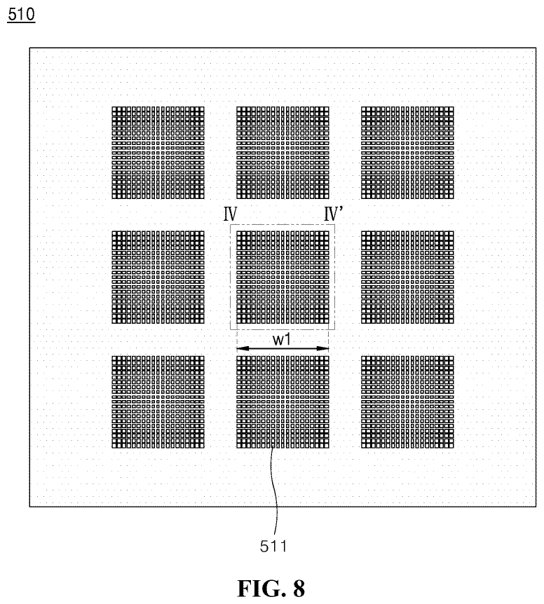

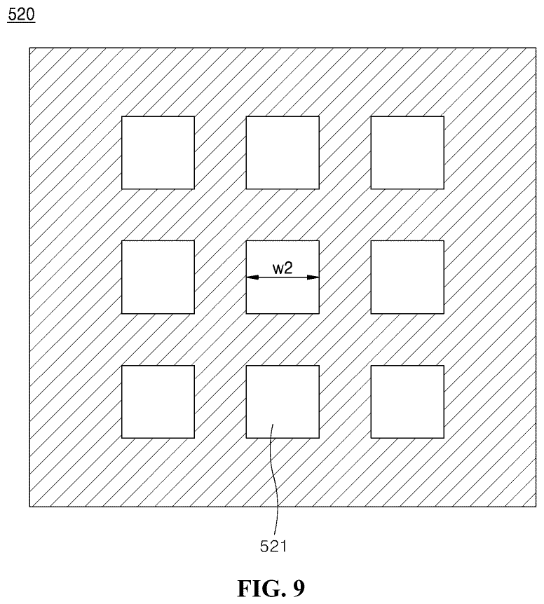

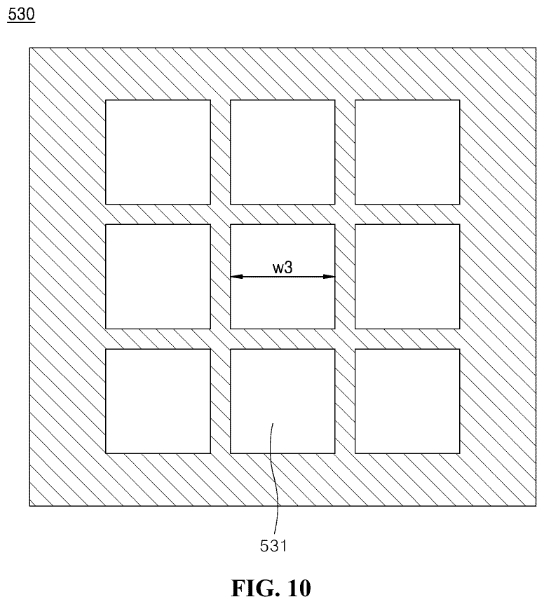

Hereinafter, a process of forming the light-emitting element layer 400 whose the thickness increases as the light-emitting element layer 400 extends from the central area CA toward the outer area OA and the mask frame assembly 50 for implementing the process will be described with further reference to FIGS. 7 to 13.

Referring to FIG. 7, a mask frame assembly 50, a mother substrate 600, and a deposition source 540 may be provided in a chamber for performing a process of depositing layers having varying thicknesses of the light-emitting element layer 400. The mask frame assembly 50 may be configured to include a support frame 500, a first mask sheet 510 disposed on the support frame 500, a second mask sheet 520 disposed on the first mask sheet 510, and a gap frame 530 disposed between the first mask sheet 510 and the second mask sheet 520. The mother substrate 600 may be disposed on the mask frame assembly 50.

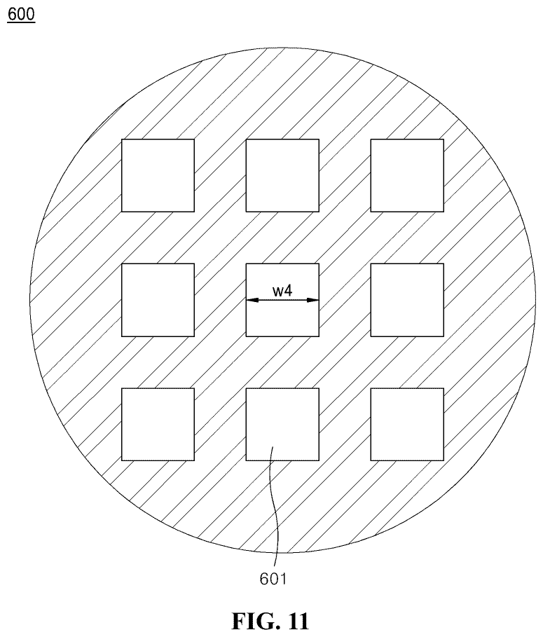

The mother substrate 600 may include a plurality of cell areas 601. In the present disclosure, for example, the plurality of cell areas 601 may be arranged in the form of a matrix arrangement of a 3×3 matrix. However, the present disclosure is not limited thereto. Referring to FIG. 11, a width of each cell area 601 of the mother substrate 600 may be defined as a fourth width w4. The circuit area 110 may be formed in each cell area 601 of the mother substrate 600. A deposition process may be performed on the mother substrate 600 in which the circuit area 110 has been formed in a chamber in which the mask frame assembly 50 is installed in order to deposit the hole transport layer HTL, the second hole transport layer HTL2, the electron transport layer ETL, and the second electron transport layer ETL2 thereon, each layer having different thicknesses depending in different areas of the light-emitting element layer 400.

The support frame 500 may support a lower surface of the first mask sheet 510. The deposition source 540 disposed under the support frame 500 may contain a deposition target material therein which may be vaporized or sublimated. The deposition target material vaporized or sublimated from the deposition source 540 may be deposited on the mother substrate 600 through the first mask sheet 510 and the second mask sheet 520.

The first mask sheet 510 may include a plurality of first openings 511 defined therein. The support frame 500 may have a shape in which a lower portion thereof is opened so that the first opening 511 of the first mask sheet 510 is exposed in a downward direction and thus the deposition target material from the deposition source 540 may pass through the opening. The plurality of first openings 511 of the first mask sheet 510 may be arranged in the same manner as the arrangement of the cell areas 601 of the mother substrate 600. The first mask sheet 510 may function as a shadow forming mask sheet for implementing a shadow effect in a deposition process. A width of each first opening 511 may be defined as a first width w1.

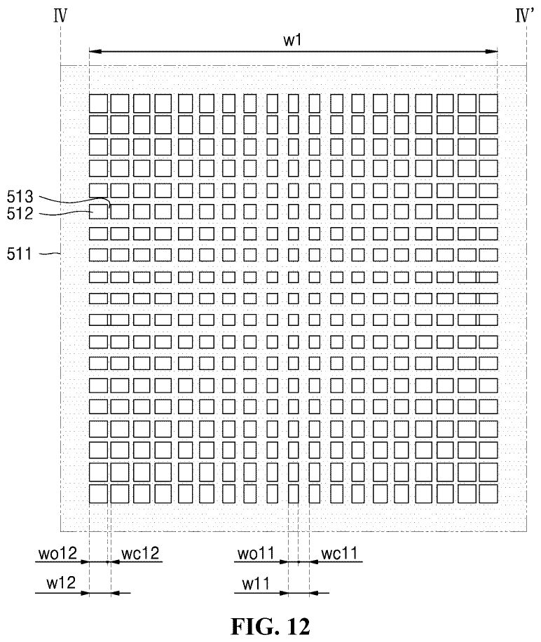

Referring to FIG. 12, each first opening 511 may include a plurality of pattern holes 512 defined by a plurality of boundary lines 513. A sum of a width of one pattern hole 512 and a width of the boundary line 513 closest to the pattern hole 512 may be constant. For example, a sum w11 of a width wo11 of a central pattern hole and a width wc11 of a central boundary line may be equal to a sum w12 of a width wo12 of the outermost pattern hole and a width wc12 of the outermost boundary line. This corresponds to a condition 1 of the mask frame assembly 50, and the condition 1 may be defined as wo11+wc11=wo12+wc12. The sizes of the pattern holes 512 of the first opening 511 may be set such that a size of the pattern hole increases as a position of the pattern hole changes from a central area of the second opening 521 toward the outer area. This corresponds to a condition 2 of the mask frame assembly 50, and the condition 2 may be defined as wo12>wo11. The light-emitting element layer 400 may be deposited such that the thickness of the light-emitting element layer 400 is increased as the light-emitting element layer 400 extends from the central area CA toward the outer area using the shadow effect based on the change in the sizes of the pattern holes 512 as described above.

The gap frame 530 may be disposed on the first mask sheet 510, and the second mask sheet 520 including a plurality of second openings 521 defined therein may be disposed on the gap frame 530. The gap frame 530 may function to support the lower surface of the second mask sheet 520 and adjust a spacing between the first mask sheet 510 and the second mask sheet 520. A height g of the gap frame 530 may be set to be greater than the sum of the width of one pattern hole 512 and the width of the boundary line 513 closest to the pattern hole 512. This corresponds to a condition 3 of the mask frame assembly 50, and the condition 3 may be defined as g>wo12+wc12. That is, the height g of the gap frame 530 may be greater than the sum of the width wo12 of the outermost pattern hole 512 located in the outermost area OA of the first opening 511 and the width wc12 of the outermost boundary line 513.

Setting the height g of the gap frame 530 as described above may allow the distance between the first mask sheet 510 and the second mask sheet 520 for implementing the shadow effect to be adjusted. The gap frame 530 may include a plurality of third openings 531 defined therein. The plurality of third openings 531 of the gap frame 530 may be arranged in the same manner as the arrangement of the cell areas 601 of the mother substrate 600. A width of the third opening 531 of the gap frame 530 may be defined as a third width w3.

The second mask sheet 520 may include the plurality of second openings 521 defined therein. The plurality of second openings 521 of the second mask sheet 520 may be arranged in the same manner as the arrangement of the cell areas 601 of the mother substrate 600. A width of the second opening 521 of the second mask sheet 520 may be defined as a second width w2. The second mask sheet 520 may function as an open mask sheet that defines an area so that the deposition target material may be deposited on the cell area 601 of the mother substrate 600, that is, an organic material deposition area for forming the light-emitting element layer. In this case, the first width w1 which is a width of the first opening 511 of the first mask sheet 510 may be set to be greater than the second width w2 which is a width of the second opening 521 of the second mask sheet 520. This corresponds to a condition 4 of the mask frame assembly 50, and the condition 4 may be defined as w1>w2.

The sizes of the widths of the respective openings as described above have a relationship of w3>w1>w2=w4. In the present disclosure, the size of the width of each of the openings means an inner diameter of each of the openings in the horizontal direction.

The display panel 10 according to the present disclosure may be formed in a following process using the mask frame assembly 50 as described above. For example, a method for forming the display panel 4 may include installing the mask frame assembly 50, mounting the mother substrate 600 including the plurality of cell areas 601 on the mask frame assembly 50, and depositing the light-emitting element layer 400 on each of the cell areas 601 through the mask frame assembly 50 using the deposition source 540 disposed under the mask frame assembly 50.

Referring to FIG. 13, the thickness of the light-emitting element layer 400 deposited in the above deposition process may increase as the light-emitting element layer 400 extends from the center area CR toward the outer area CR in each of the cell areas 601 disposed on each mother substrate 600. Each of the cell areas 601 may be an individual display panel 10. Thus, after the light-emitting element layer 400 has been deposited, the plurality of display panels 10 may be obtained from the mother substrate 600 via a cutting process of each of the light-emitting element layer 400 into the cell areas 601. In this case, the substrate itself constituting the mother substrate 600 may be a substrate supporting a lower surface of the display panel 10.

According to the above-described embodiment of the present disclosure, the thickness in the outer area of the light-emitting element layer of the display panel is larger than the thickness in the central area thereof, thereby improving the viewing angle characteristic in the outer area of the display panel.

In addition, according to an embodiment of the present disclosure, the light-emitting element layer may be deposited such that the thickness in the outer area of the light-emitting element layer of the display panel is larger than the thickness in the central area of the light-emitting element layer, using the mask frame assembly including the first mask sheet functioning as a shadow forming mask sheet in which the sizes of the pattern holes of the first opening are set such that a size of the pattern hole increases as a position of the pattern hole changes from the central area toward the outer area, and the second mask sheet functioning as an open mask sheet.

In addition, according to an embodiment of the present disclosure, the microcavity effect in the outer area of the display panel to which the microcavity structure is applied may be adjusted to optimize the viewing angle characteristic, thereby reducing the occurrence of the luminance reduction problem and the color distortion problem of the display panel.

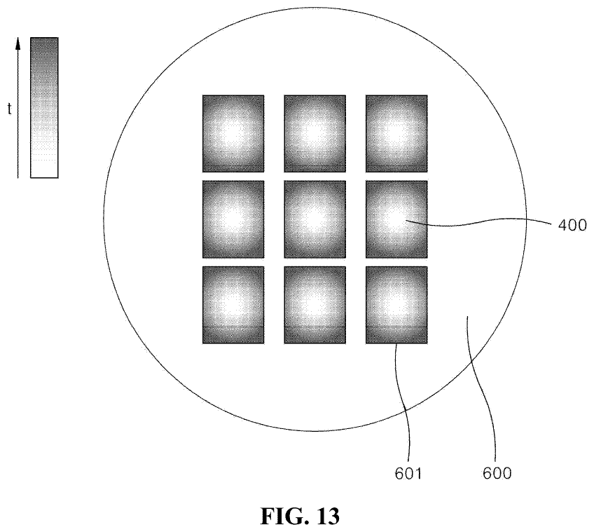

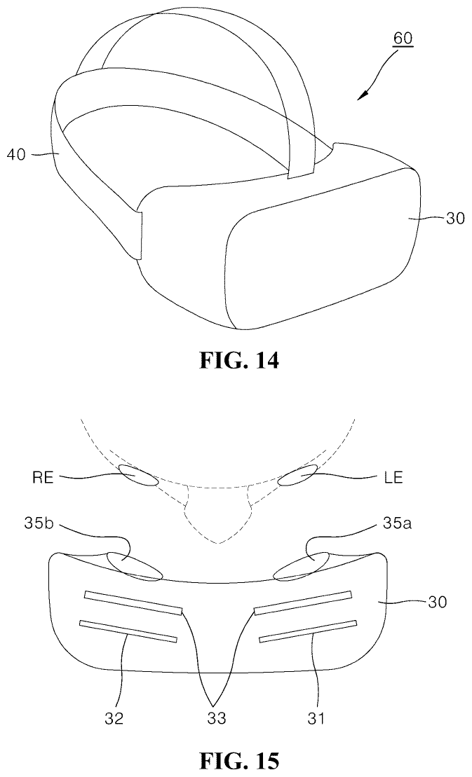

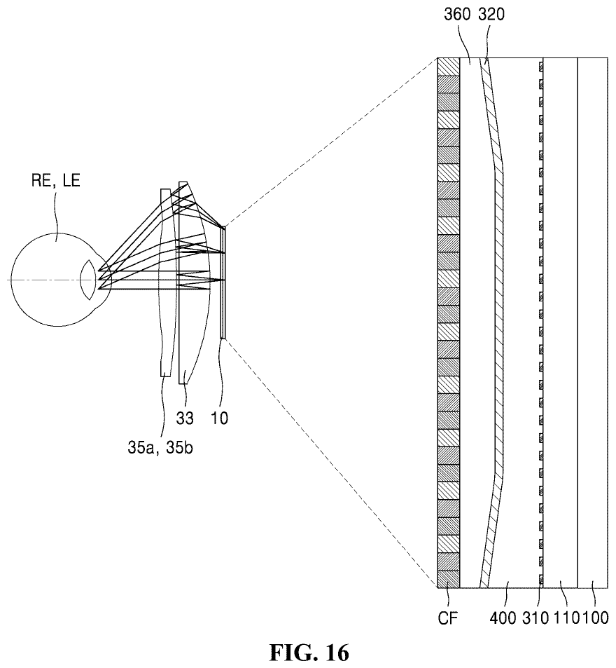

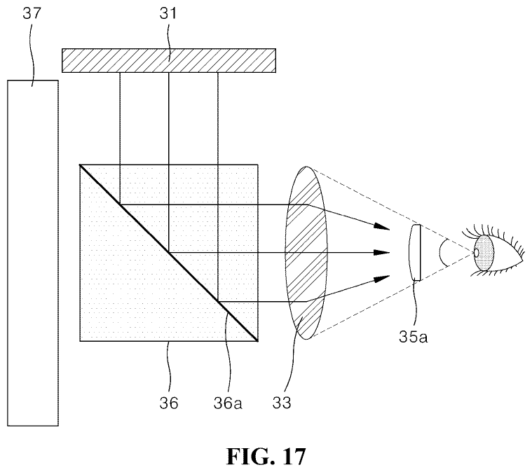

FIGS. 14 to 17 are diagrams of head-mounted display apparatuses including a display device according to an embodiment of the present disclosure. Specifically, FIG. 14 is a schematic perspective view of a head-mounted display apparatus including a display device according to an embodiment of the present disclosure. FIG. 15 and FIG. 16 are top and side views showing a head-mounted display apparatus implementing virtual reality, respectively, according to an embodiment of the present disclosure. FIG. 17 is a side view showing a head-mounted display apparatus that implements augmented reality according to an embodiment of the present disclosure.

Referring to FIG. 14, the head-mounted display apparatus 60 including a display device according to an embodiment of the present disclosure may include a casing 30 and a head mounting band 40. The casing 30 may receive therein components such as a display device, a lens array, an eyepiece, a sound device, an accelerometer, and a position sensor, etc. The head mounting band 40 is fixed to the casing 30. The head mounting band 40 is illustrated as being formed to surround an upper surface and both opposing side surfaces of the user's head. However, embodiments of the present disclosure are not limited thereto. The head mounting band 40 is used to secure the head-mounted display apparatus 60 to the user's head. In another example, the head mounting band 40 may be embodied as an eyeglass frame or a helmet-shaped structure that entirely surrounds the user's head. The head-mounted display apparatus 60 may include the display device according to an embodiment of the present disclosure as described above, and may provide an image implementing virtual reality (VR) or an image implementing augmented reality (AR) to the user.

Referring to FIG. 15 and FIG. 16, the head-mounted display apparatus 60 implementing virtual reality may include a first display panel 31, a second display panel 32, a first lens 33, a left eye eyepiece 35a, and a right eye eyepiece 35b. In this case, based on FIG. 16, the display panel 10 may be the first display panel 31 or the second display panel 32. The first display panel 31 may be referred to as a left-eye display panel, the second display panel 32 may be referred to as a right-eye display panel, the first lens 33 may be referred to as a lens array, and the left-eye eyepiece 35a and the right-eye eyepiece 35b may be referred to as a pair of second lenses. The first display panel 31, the second display panel 32, the first lens 33, and the left-eye eyepiece 35a and the right-eye eyepiece 35b may be accommodated in the casing 30.

The first display panel 31 and the second display panel 32 may display the same image. When the same image is implemented in the first display panel 31 and the second display panel 32, respectively, the user may watch the 2D image through the head-mounted display apparatus 60. Alternatively, the first display panel 31 may display a left-eye image, and the second display panel 32 may display a right-eye image different from the left-eye image. In this case, the user may view the stereoscopic image through the head-mounted display apparatus 60. Each of the first display panel 31 and the second display panel 32 may include one of the display panel according to the above-described embodiment of the present disclosure and a modified example thereof.

The first lens 33 may be spaced apart from each of the left eye eyepiece 35a and the first display panel 31, and may be disposed between the left eye eyepiece 35a and the first display panel 31. That is, the first lens 33 may be positioned in front of the left eye eyepiece 35a and in rear of the first display panel 31. In addition, the first lens 33 may be spaced apart from each of the right-eye eyepiece 35b and the second display panel 32, and may be disposed between the right-eye eyepiece 35b and the second display panel 32. That is, the first lens 33 may be positioned in front of the right eye eyepiece 35b and in rear of the second display panel 32. The first lens 33 may include a micro lens array. However, embodiments of the present disclosure are not limited thereto. In an example, the first lens 33 may include a pinhole array. The image displayed on the first display panel 31 or the second display panel 32 via the first lens 33 may be visible to the user in an enlarged manner. A left eye LE of the user may be positioned in rear of the left eye eyepiece 35a, and a right eye RE of the user may be positioned in rear of the right eye eyepiece 35b.

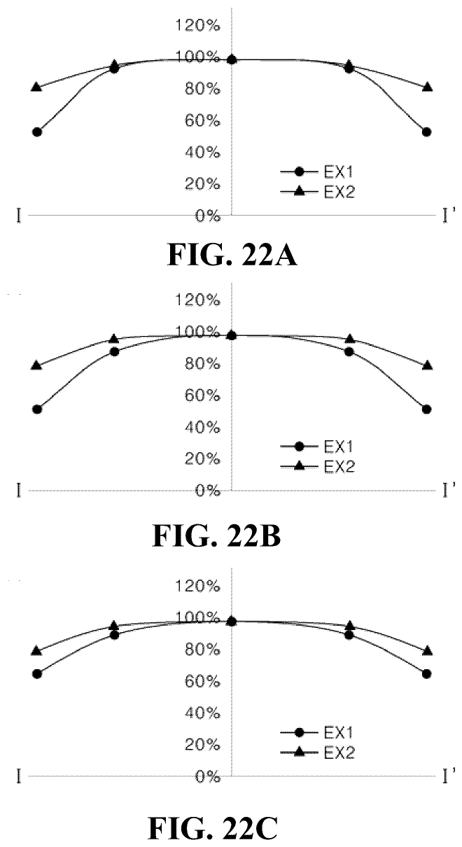

Referring to FIG. 17, the head-mounted display apparatus 60 implementing augmented reality may include the first display panel 31, the first lens 33, a second lens 35a, a transmissive and reflective portion 36, and a transmissive window 37. For convenience of description, only the configuration of the left eye is illustrated in FIG. 22, and the configuration of the right eye may be the same as or similar to the configuration of the left eye.

The first display panel 31, the first lens 33, the second lens 35a, the transmissive and reflective portion 36, and a transmissive window 37 may be accommodated in the casing 30. The first display panel 31 may be disposed on one side of the transmissive and reflective portion 36, for example, on an upper side thereof so that the first display panel 31 does not block the transmissive window 37. Accordingly, the first display panel 31 may provide an image to the transmissive and reflective portion 36 without blocking an external background visible through the transmissive window 37. The first display panel 31 may include one of the display panel according to the above-described embodiment of the present disclosure and a modified example thereof. The first lens 33 may be provided between the second lens 35a and the transmissive and reflective portion 36. The user's left eye is positioned in rear of the second lens 35a.

The transmissive and reflective portion 36 is disposed between the first lens 33 and the transmissive window 37. The transmissive and reflective portion 36 may include a transmissive and reflective surface 36a that transmits a portion of light therethrough and reflects the other portion of light therefrom. The transmissive and reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The transmissive and reflective surface 36a may be formed to allow the image displayed from the first display panel 31 to be directed to the first lens 33. Therefore, the user may view both the external background visible through the transmissive window 37 and the image displayed from the first display panel 31. In other words, the user may view both the real background and the virtual image as one image in an overlapping manner. Thus, the augmented reality may be implemented.

According to an embodiment of the present disclosure described above, the head-mounted display apparatus may be implemented using the display panel having improved viewing angle characteristics, thereby providing a consistent visual experience to a user and maximizing a user's immersion.

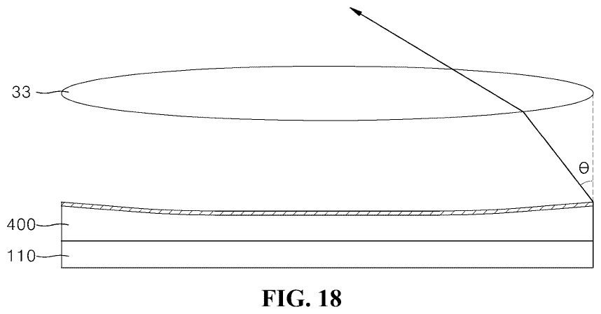

FIG. 18 illustrates an incident angle θ at which light from an edge area of the light-emitting element layer 400 is incident on the lens 33. Referring to FIG. 3 together, when a thickness in a central area of the light-emitting element layer 400 is defined as t and a thickness at an outermost line of the light-emitting element layer 400 is defined as t', a relationship about the thickness of the light-emitting element layer 400 may be defined as follows. The relationship of the thickness of the light-emitting element layer may be defined as t>t′ and cosθ>t/t′.

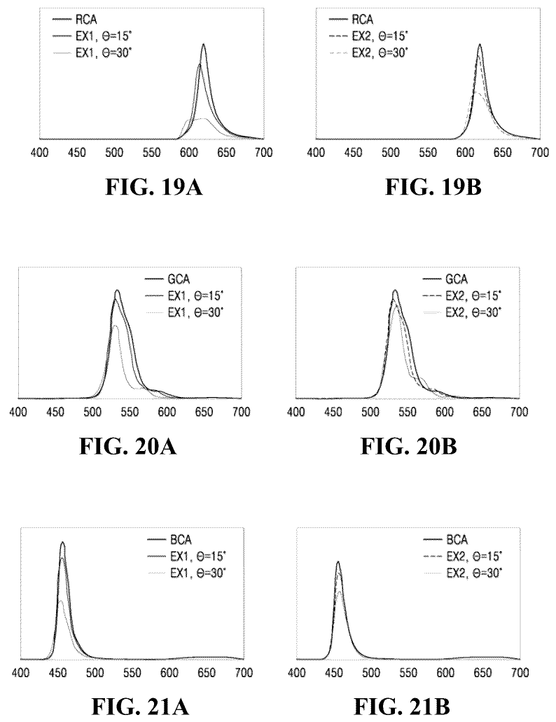

FIGS. 19A, 19B, 20A, 20B, 21A, and 21B show spectra according to a different viewing angles, that is, an incident angle θ according to Embodiment and Comparative Example. The x-axis of FIGS. 19A, 19B, 20A, 20B, 21A, and 21B means a wavelength, and the unit thereof may be nm. In addition, EX1 refers to a Comparative Example in which the thickness of the light-emitting element layer is constant, and EX2 refers to the Embodiment in which the thickness of the light-emitting element layer becomes larger as the light-emitting element layer extends from the center toward the edge.

Referring to FIG. 19A is directed to the Comparative Example EX1 in which a spectrum of red light RCA in a central area, and a spectrum in which an incident angle θ in an edge area is each of 15° and 30° are compared with each other. FIG. 19B is directed to the Embodiment EX2 in which a spectrum of red light RCA in a central area, and a spectrum in which an incident angle θ in an edge area is each of 15° and 30° are compared with each other. Based on the graph of FIGS. 19A and 19B, it may be identified that the spectra of the Comparative Example EX1 and the Embodiment EX2 exhibit relatively similar peaks in the central area. It may be identified that when the incident angle θ at the edge area is 15°, the spectral peak is significantly lowered compared to the central area in the Comparative Example EX1, while in the Embodiment EX2, the relatively high light emission intensity is maintained even at the 15° angle and the peak similar to that in the central area is maintained in the edge area. It may be identified that when the incident angle θ at the edge area is 30°, the spectral peak is further reduced in the Comparative Example EX1, while in the Embodiment EX2, there is no significant difference between the spectral peak in the central area even and the spectral peak at the incident angle 30° in the edge area, and the luminous efficiency is improved.

FIGS. 20A, 20B, 21A, and 21B are graphs of Comparative Example EX1 and Embodiment EX2 about spectra of green light GCA and blue light BCA, respectively. Based on FIGS. 20A, 20B, 21A, and 21B, it may be identified that in the Embodiment EX2, luminous efficiency in the edge area is greatly improved compared to the Comparative Example EX1.

FIGS. 22A, 22B, and 22C illustrate a luminance deviation based on a position according to Embodiment and Comparative Example. FIG. 22A shows a luminance deviation based on a position of red light, FIG. 22B shows a luminance deviation based on a position of green light, and FIG. 22C shows a luminance deviation based on a position of blue light. The y-axis of FIG. 22A and represents a relative ratio (%) of luminance, and luminance in the central area of the display panel is defined as 100%. As may be identified in FIGS. 22A, 22B, and 22C, it may be identified that the deviation between the luminance of the central area and the luminance of the outer area is significantly reduced in the Embodiment EX2, compared to the Comparative Example EX1 in each of the red light, the green light, and the blue light, and thus it may be identified that the Embodiment EX2 has a relatively uniform distribution throughout the display panel.

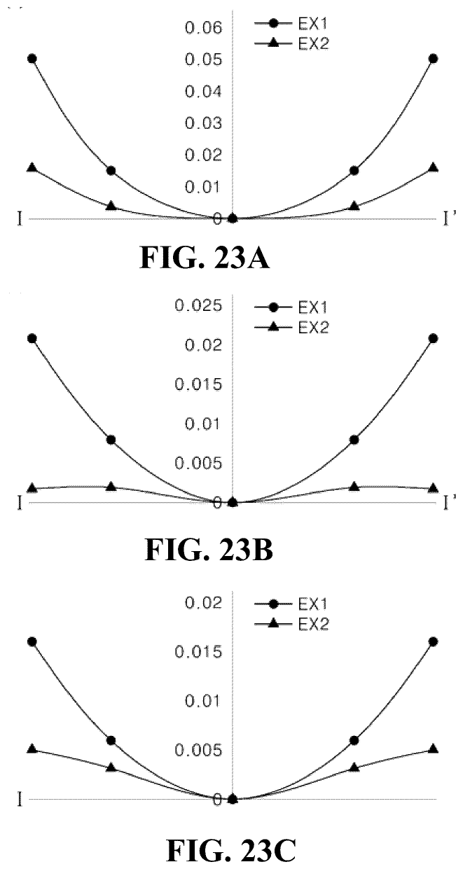

FIGS. 23A, 23B, and 23C show a color deviation based on a position according to Embodiment and Comparative Example. FIG. 23A shows a color deviation based on a position of red light, and FIG. 23B shows a color deviation based on a position of green light. Further, a color deviation based on a position of blue light is illustrated in FIG. 23C. The y-axis of FIG. 23A. 23B and 23C represents a color deviation, and the lower the value, the higher the color uniformity. As may be identified in FIG. 23A. 23B and 23C, it may be identified that the deviation between the color of the central area and the color of the outer area is significantly reduced in the Embodiment EX2 compared to the Comparative Example EX1 in each of the red light, the green light, and the blue light, and thus it may be identified that the Embodiment EX2 has a relatively uniform distribution throughout the display panel.

In the display panel and the display device according to an embodiment of the present disclosure as described above, the difference between the luminance of the central area and the luminance of the outer area of the light-emitting element layer and the difference between the color of the central area and the color of the outer area of the light-emitting element layer are greatly reduced, such that the screen uniformity of the display panel is improved, thereby improving the image quality of the display device and improving the viewing experience of the user.

The display panel, the display device, the mask frame assembly, and the method for manufacturing the display panel according to aspects and embodiments of the present disclosure as described above may be described as follows.

A first embodiment of the present disclosure provides a display panel comprising: a substrate having a plurality of pixel areas corresponding to a plurality of pixels; a light-emitting element layer disposed on the substrate and extending across the plurality of pixel areas, wherein the light-emitting element layer constitutes the plurality of pixels, wherein a thickness of the light-emitting element layer in an outer area of the display panel is greater than a thickness of the light-emitting element layer in a central area of the display panel.

In accordance with some embodiments of the display panel, the thickness of the light-emitting element layer increases as the light-emitting element layer extends from the central area to the outer area.

In accordance with some embodiments of the display panel, the thickness of the light-emitting element layer increases in a gradation manner.

In accordance with some embodiments of the display panel, the light-emitting element layer includes at least one of a hole transport layer and an electron transport layer, wherein a thickness of each of the hole transport layer and the electron transport layer increases as each of the hole transport layer and the electron transport layer extends from the central area toward the outer area.

In accordance with some embodiments of the display panel, the light-emitting element layer includes at least one of a hole injection layer, a light-emitting layer, and a charge generation layer, wherein each of the hole injection layer, the light-emitting layer, and the charge generation layer has a constant thickness as each of the hole injection layer, the light-emitting layer, and the charge generation layer extends from the central area toward the outer area.

In accordance with some embodiments of the display panel, the light-emitting element layer continuously extends across the plurality of pixel areas.

In accordance with some embodiments of the display panel, the display panel further comprises a plurality of reflective electrodes disposed between the substrate and the light-emitting element layer; each first electrode disposed between the light-emitting element layer and each of the reflective electrodes; and a second electrode disposed on the light-emitting element layer, wherein each pixel includes a plurality of sub-pixels, wherein respective distances between the respective reflective electrodes corresponding to the sub-pixels emitting light of different colors and the second electrode are different from each other.

In accordance with some embodiments of the display panel, respective distances between the respective reflective electrodes corresponding to the sub-pixels emitting light of the same color and the second electrode are set such that the distance between the reflective electrode in a corresponding sub-pixel and the second electrode is larger as the corresponding sub-pixel is father from the central area and is closer to the outer area.

In accordance with some embodiments of the display panel, the light-emitting element layer are divided into areas by: a center line passing through a center of the light-emitting element layer; outermost lines respectively positioned at both opposing ends of the light-emitting element layer; and a middle line positioned between the center line and the outermost line, wherein a thickness change rate of the light-emitting element layer in a second area between the middle line and the outermost line is greater than a thickness change rate of the light-emitting element layer in a first area between the central line and the middle line.

In accordance with some embodiments of the display panel, an encapsulation layer disposed on the light-emitting element layer, wherein a thickness of the encapsulation layer decreases as the encapsulation layer from the central area to the outer area.

A second embodiment of the present disclosure provides a display device, comprising: a casing; and at least one display panel accommodated in the casing, wherein each of the at least one display panel includes the display panel as described above.

In accordance with some embodiments of the display device, the at least one display panel includes a first display panel and a second display panel spaced apart from each other, wherein the casing further accommodates therein a left eye lens disposed between the first display panel and a left eye of a user, and a right eye lens disposed between the second display panel and a right eye of the user.

A third embodiment of the present disclosure provides a mask frame assembly comprising: a support frame; a first mask sheet disposed on the support frame and having a plurality of first openings defined therein, each first opening including a plurality of pattern holes defined by a plurality of boundary lines; a second mask sheet disposed on the first mask sheet and having a plurality of second openings defined therein; and a gap frame disposed between the first mask sheet and the second mask sheet and having a plurality of third openings defined therein, wherein sizes of the pattern holes arranged in the first opening sequentially increase as the pattern holes are sequentially arranged in a direction from a central area of the first opening toward an outer area thereof.

In accordance with some embodiments of the mask frame assembly, a width of the first opening is greater than a width of the second opening.

In accordance with some embodiments of the mask frame assembly, a width of the third opening is greater than a width of the first opening.

In accordance with some embodiments of the mask frame assembly, a sum of a width of the pattern hole and a width of the boundary line closest to the pattern hole is constant.

In accordance with some embodiments of the mask frame assembly, a height of the gap frame is greater than a sum of a width of an outermost pattern hole positioned in an outermost area of the first opening and a width of an outermost boundary line of the first opening.

A fourth aspect of the present disclosure provides a method for manufacturing a display panel, the method comprising: installing the mask frame assembly as described above, mounting a mother substrate including a plurality of cell areas on the mask frame assembly; and depositing a light-emitting element layer on each of the cell areas through the mask frame assembly using a deposition source disposed under the mask frame assembly.

In accordance with some embodiments of the method for manufacturing the display panel, the light-emitting element layer includes at least one of a hole transport layer and an electron transport layer.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display panel comprising:
a substrate having a plurality of pixel areas corresponding to a plurality of pixels;
a light-emitting element layer on the substrate, the light-emitting element layer corresponding to the plurality of pixels,
wherein the light-emitting element layer has a thickness that is greater in an outer area than in a central area thereof.

2. The display panel of claim 1, wherein the thickness of the light-emitting element layer gradually increases from the central area toward the outer area.

3. The display panel of claim 2, wherein the thickness of the light-emitting element layer increases in a gradient manner.

4. The display panel of claim 2, wherein the light-emitting element layer includes at least one of a hole transport layer and an electron transport layer,
wherein a thickness of each of the hole transport layer and the electron transport layer increases from the central area toward the outer area.

5. The display panel of claim 2, wherein the light-emitting element layer includes at least one of a hole injection layer, a light-emitting layer, and a charge generation layer,
wherein each of the hole injection layer, the light-emitting layer, and the charge generation layer has a constant thickness across the central area and outer area.

6. The display panel of claim 1, wherein the light-emitting element layer continuously extends across the plurality of pixel areas.

7. The display panel of claim 1, further comprising:
a plurality of reflective electrodes between the substrate and the light-emitting element layer;
a first electrode between the light-emitting element layer and each of the plurality of reflective electrodes; and
a second electrode on the light-emitting element layer,
wherein each of the plurality of pixels includes a plurality of sub-pixels,
wherein distances between the plurality of reflective electrodes corresponding to sub-pixels of different colors and the second electrode are different.

8. The display panel of claim 7, wherein distances between the plurality of reflective electrodes corresponding to sub-pixels of a same color and the second electrode increase from the central area toward the outer area.

9. The display panel of claim 1, wherein the light-emitting element layer is divided into a plurality of areas by:
a center line passing through a center of the light-emitting element layer;
outermost lines respectively positioned at both opposing ends of the light-emitting element layer; and
a middle line positioned between the center line and an outermost line from the outermost lines,
wherein a thickness change rate of the light-emitting element layer in a second area between the middle line and the outermost line is greater than a thickness change rate of the light-emitting element layer in a first area between the center line and the middle line.

10. The display panel of claim 1, further comprising:
an encapsulation layer on the light-emitting element layer,
wherein a thickness of the encapsulation layer decreases from the central area toward the outer area.

11. A display device, comprising:
a casing; and
at least one display panel accommodated in the casing, wherein the at least one display panel includes the display panel according to one of claim 1.

12. The display device of claim 11, wherein the at least one display panel includes a first display panel and a second display panel spaced apart from each other,
wherein the casing further accommodates therein a left eye lens between the first display panel and a left eye of a user, and a right eye lens between the second display panel and a right eye of the user.

13. A mask frame assembly comprising:
a support frame;
a first mask sheet on the support frame, the first mask sheet having a plurality of first openings defined therein where each first opening including a plurality of pattern holes defined by a plurality of boundary lines;
a second mask sheet on the first mask sheet, the second mask sheet having a plurality of second openings defined therein; and
a gap frame between the first mask sheet and the second mask sheet, the gap frame having a plurality of third openings defined therein,
wherein sizes of the plurality of pattern holes in each of the plurality of first openings increase from a central area toward an outer area.

14. The mask frame assembly of claim 13, wherein a width of a first opening from the plurality of first openings is greater than a width of a second opening from the plurality of second openings.

15. The mask frame assembly of claim 13, wherein a width of a third opening from the plurality of third openings is greater than a width of a first opening from the plurality of first openings.

16. The mask frame assembly of claim 13, wherein a sum of a width of a pattern hole from the plurality of pattern holes and a width of a boundary line from the plurality of boundary lines that is closest to the pattern hole is constant.

17. The mask frame assembly of claim 13, wherein a height of the gap frame is greater than a sum of a width of an outermost pattern hole from the plurality of pattern holes that is positioned in an outermost area of a first opening from the plurality of first openings and a width of an outermost boundary line of the first opening.

18. A method for manufacturing a display panel, the method comprising:
installing the mask frame assembly according to claim 13;
mounting a mother substrate including a plurality of cell areas on the mask frame assembly; and
depositing a light-emitting element layer on each of the plurality of cell areas through the mask frame assembly using a deposition source disposed under the mask frame assembly.

19. The method for manufacturing the display panel of claim 18, wherein the light-emitting element layer includes at least one of a hole transport layer and an electron transport layer.
